(19) United States
(12) Patent Application Publication
(10) Pub. No.: US 2009/0231170 A1
(43) Pub. Date: Sep. 17, 2009

(54) APPARATUS AND METHOD FOR DIGITAL FREQUENCY DOWN-CONVERSION

(75) Inventors: Yo-An Jung, Gyeonggi-do (KR); Young-Jae Cha, Gyeonggi-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Posdata Co., Ltd, Kyeonggi-do (KR)

(21) Appl. No.: 12/294,238

(22) PCT Filed: Mar. 30, 2007
(86) PCT No.: PCT/KR2007/001570

§ 371 Date: Sep. 23, 2008

(30) Foreign Application Priority Data
Mar. 30, 2006 (KR) 10 2006 0029197

(51) Int. Cl. H03M 7/00; H03M 9/00; H03M 1/12

(52) U.S. Cl. 341/61; 341/100; 341/155

(57) ABSTRACT

Disclosed is an apparatus and a method for down-converting frequencies of an input signal by separating the signal to which at least two frequencies are allocated according to each frequency, and then outputting at least two digital IF signals in a communication system. The digital down-converting apparatus includes a band-pass filter, an analog-to-digital converter, down-converters, up-converters, and Serializer/Deserializeres, etc. First, the signal to which at least two frequencies are allocated is down-converted into baseband signals respectively. Then, the baseband signals are up-converted into signals of a predetermined frequency respectively.

### TECHNICAL FIELD

The present invention relates to an apparatus and a method for digital frequency down-conversion, and more particularly to an apparatus and a method for separating analog Intermediate Frequency (IF) signals from a composite analog IF signal including at least two frequencies according to each frequency, down-converting separated analog IF signals respectively, and then outputting at least two digital IF signals in a communication system.

### BACKGROUND ART

FIG. 1 is a block diagram illustrating the structure of an apparatus for analog IF down-conversion according to the prior art. The apparatus for analog IF down-conversion illustrated in FIG. 1 exemplifies a device which separates a composite analog IF signal to which three Frequencies are Allocated (hereinafter, referred to as “FA”) into analog IF signals according to each frequency, down-converts separated analog IF signals, converts a down-converted analog IF signals into digital IF signals, and outputs the digital IF signals.

As illustrated in FIG. 1, the apparatus for analog IF down-conversion includes Band-Pass Filters (BPFs), Local Oscillators (LOs), mixers, Analog-to-Digital Converters (ADCs), Serializer/Deserializers (SerDeses), etc.

First, a 3FA BPF 110 filters a composite analog IF signal to which three Frequencies, e.g., f_{O1}=66 [MHz], f_{O2}=75 [MHz], and f_{O3}=84 [MHz] are Allocated (hereinafter, referred to as “3FA”) with a center frequency f_{OA}=75 [MHz] and band width (BW)=30 [MHz], and provides a filtered composite analog IF signal to first, second, and third BPFs.

The first, second, and third BPFs 121, 122, and 123 respectively separates, according to frequencies, analog IF signals from the 3FA composite analog IF signal that has passed through the 3FA BPF. Namely, the first BPF 121 filters the 3FA composite analog IF signal with f_{O1}=66 [MHz] and BW=10 [MHz], and separates a first analog IF signal from the 3FA composite analog IF signal. The second BPF 122 filters the 3FA composite analog IF signal with f_{O2}=75 [MHz] and BW=10 [MHz], and separates a second analog IF signal from the 3FA composite analog IF signal. The third BPF 123 filters the 3FA composite analog IF signal with f_{O3}=84 [MHz] and BW=10 [MHz], and separates a third analog IF signal from the 3FA composite analog IF signal.

Meanwhile, each of the local oscillators 131, 132, and 133 generates the local frequency for down-conversion, and provides the generated local frequency to the relevant mixer. Namely, the first local oscillator 131 generates a first local frequency f_{L1}, and provides the first local frequency f_{L1} to the first mixer 141. The second local oscillator 132 generates a second local frequency f_{L2}, and provides the second local frequency f_{L2} to the second mixer 142. The third local oscillator 133 generates a third local frequency f_{L3}, and provides the third local frequency f_{L3} to the third mixer 143. The first, second, and third local frequencies respectively correspond to the minimum frequency limits (or magnitudes) related to the first, second, and third analog IF signals. To cite an instance, in a case where the down-conversion to an IF signal of the center frequency f_{O}=15 [MHz] is performed, then f_{L1}=51 [MHz], f_{L21}=60 [MHz], and f_{L3}=69 [MHz]. Also, the local oscillator is embodied including a Phase-Locked Loop (PLL) in order to provide a stable frequency without being affected by the ambient environment (i.e., ambient circuits, ambient devices, temperature, weather, etc.).

Each of the mixers 141, 142, and 143 mixes the analog IF signal of f_{O}=15 [MHz] provided after being separated from the 3FA composite analog IF signal according to each frequency and the local frequency f_{L} provided from the local oscillator. Namely, the first mixer mixes the first analog IF signal provided from the first BPF and the first local frequency provided from the first local oscillator, and generates a first analog IF signal (i.e., f_{O}=f_{O1}−f_{L1}=15 [MHz]) whose frequency is down-converted into the frequency corresponding to a difference (i.e., f_{O1}−f_{L1}) therebetween. The second mixer mixes the second analog IF signal provided from the second BPF and the second local frequency provided from the second local oscillator, and generates a second analog IF signal (i.e., f_{O}=f_{O2}−f_{L2}=15 [MHz]) whose frequency is down-converted into the frequency corresponding to a difference (i.e., f_{O2}−f_{L2}) therebetween. The third mixer mixes the third analog IF signal provided from the third BPF and the third local frequency provided from the third local oscillator, and generates a third analog IF signal (i.e., f_{O}=f_{O3}−f_{L3}=15 [MHz]) whose frequency is down-converted into the frequency corresponding to a difference (i.e., f_{O3}−f_{L3}) therebetween.

Each of the ADCs 151, 152, and 153 converts the analog signal of f_{O}=15 [MHz] into a digital IF signal of n bits (n is a natural number) by using a sampling clock of, e.g., 60 [MHz]. Namely, the first, second, and third ADCs respectively convert the first, second, and third analog IF signals, all having f_{O}=15 [MHz] provided from the first, second, and third mixers, into the first, second, and third digital IF signals, all having n bits and f_{O}=15 [MHz], and respectively transmit the first, second, and third digital IF signals to the first, second, and third SerDeres.

The SerDeses 161, 162, and 163 converts parallel digital IF signals transmitted from the ADCs into serial signals, transmits converted digital IF signals to, e.g., channel cards, etc. Namely, the first SerDes 161 converts the first parallel digital IF signal (f_{O}=15 [MHz]) transmitted from the first ADC into the serial signal, and transmits the converted first digital IF signal to the first channel card. The second SerDes 162 converts the second parallel digital IF signal (f_{O}=15 [MHz]) transmitted from the second ADC into the serial signal, and transmits the converted second digital IF signal to the second channel card. The third SerDes 163 converts the third parallel digital IF signal (f_{O}=15 [MHz]) transmitted from the third ADC into the serial signal, and transmits the converted third digital IF signal to the third channel card.

Still, as the number of down-conversion paths and local oscillators (i.e., PLL) increases by allocation of frequencies in the apparatus and the method for analog IF down-conversion according to the prior art, problems appear in that the apparatus becomes complex, and that it needs much time to debugging. Moreover, harmonic components by modulation can affect other frequencies, and, it is problematic that a group delay and the degradation of phase characteristics are caused in a case where a band-pass filter having excellent cut-off characteristics is utilized. Besides, in a case where control is performed by allocation of frequencies (e.g., in the case of a change to 1FA, 2FA, and 3FA), problems appear in that it is difficult to implement the control since a local output of a PLL can be generated.

In the meantime, owing to the rapid growth of technological development in a field of semiconductors, recently, an Analog-to-Digital Converter (ADC) and a DAC whose sampling rates are nearly 100 [Msps] have been developed, and accordingly, the direct digital conversion between an IF band signal and a baseband signal can be implemented. In addition, as the performances of digital signal processing devices such as a general-purpose Digital Signal Processor (DSP) and a Field Programmable Gate Array (FPGA) become excellent, it is possible to embody both a baseband modem that can be reconfigured in a form of software and an improved signal processing module.

However, despite the progress of digital signal processing technology, in a case where the apparatus for analog IF down-conversion according to the aforementioned prior art is directly embodied by an apparatus for digital IF conversion, as a system clock of high-frequency should be used in order to actualize a digital IF having high-frequency approaching 100 [MHz], there still exist problems such that the configuration and design of the apparatus are complex, and an embodiment thereof is difficult.

### DISCLOSURE OF INVENTION

### Technical Problem

Accordingly, the present invention has been made to solve the above problems occurring in the prior art, and it is an aspect of the present invention to provide an apparatus and a method for digital frequency down-conversion, which separate digital IF signals from a composite digital IF signal including at least two frequencies according to each frequency, down-convert the digital IF signals into baseband signals respectively, up-convert the down-converted signals into signals having the predetermined reference frequencies coinciding with protocol, and output at least two digital IF signals.

Furthermore, it is another aspect of the present invention to provide an apparatus and a method for digital frequency down-conversion whose configuration and design are simple, and whose debugging is easy.

### Technical Solution

In accordance with one aspect of the present invention, there is provided an apparatus for digital frequency down-conversion according to an embodiment of the present invention, including: a first down-converter for receiving a composite digital signal having the center frequencies f_{O1} and f_{O2}, which includes a first digital signal of the center frequency f_{O1} and a second digital signal of the center frequency f_{O2}, and converting the first digital signal of the center frequency f_{O1} into a first baseband digital signal; a second down-converter for receiving the composite digital signal having the center frequencies f_{O1} and f_{O2}, and converting the second digital signal of the center frequency f_{O2} into a second baseband digital signal; a first up-converter for receiving the first baseband digital signal from the first down-converter, and converting the received first baseband digital signal into a first digital signal of the reference center frequency f_{OU} lower than the mean of the center frequencies f_{O1} and f_{O2}; and a second up-converter for receiving the second baseband digital signal from the second down-converter, and converting the received second baseband digital signal into a second digital signal of the reference center frequency f_{OU} lower than the mean of the center frequencies f_{O1} and f_{O2}.

In accordance with another aspect of the present invention, there is provided an apparatus for digital frequency down-conversion according to an embodiment of the present invention, including: an Analog-to-Digital Converter (ADC) for converting a composite analog signal having at least two center frequencies into a composite digital signal having at least two center frequencies; a Field Programmable Gate Array (FPGA) for receiving the composite digital signal from the ADC, respectively down-converting at least two digital signals having each center frequency included in the composite digital signal into baseband digital signals, and respectively up-converting the baseband digital signals into digital signals having the reference center frequency; and a Serializer/Deserializer (SerDes) for converting the parallel digital signals of the reference center frequency provided from the FPGA into the serial digital signals of the reference center frequency.

In accordance with another aspect of the present invention, there is provided a method for digital frequency down-conversion according to an embodiment of the present invention, including the steps of: (a) separating first and second digital signals respectively having the center frequencies f_{O1} and f_{O2} from a composite digital signal having the center frequencies f_{O1} and f_{O2}, and down-converting the composite digital signal having the center frequencies f_{O1} and f_{O2} into first and second baseband digital signals; and (b) up-converting the first and second baseband digital signals into first and second digital signals having the reference center frequency f_{OU} lower than the center frequencies f_{O1} and f_{O2}, respectively.

### ADVANTAGEOUS EFFECTS

An apparatus and a method for digital frequency down-conversion according to the present invention, which separate digital IF signals from a composite digital IF signal including at least two frequencies according to each frequency, down-convert the digital IF signals into baseband signals, up-convert down-converted signals into signals having the predetermined frequencies, and output at least two digital IF signals. Accordingly, as the frequency of a system clock is lowered, power consumption and expenses can be reduced.

Also, the apparatus and the method for digital frequency down-conversion according to the present invention can prevent the deterioration of signal characteristics caused by harmonic components generated in the prior analog signal processing scheme by using the technology of digital signal processing, and therefore, can improve the quality of an output signal.

Moreover, it is simple to configure and design the apparatus for digital frequency down-conversion according to the present invention by using a Field-Programmable Gate Array (FPGA) that can be reconfigured, and accordingly, it is easy to debug the apparatus.

### BRIEF DESCRIPTION OF THE DRAWINGS

The above and other exemplary features, aspects, and advantages of the present invention will be more apparent from the following detailed description taken in conjunction with the accompanying drawings, in which:

FIG. 1 is a block diagram illustrating the structure of an apparatus for analog IF down-conversion according to the prior art;

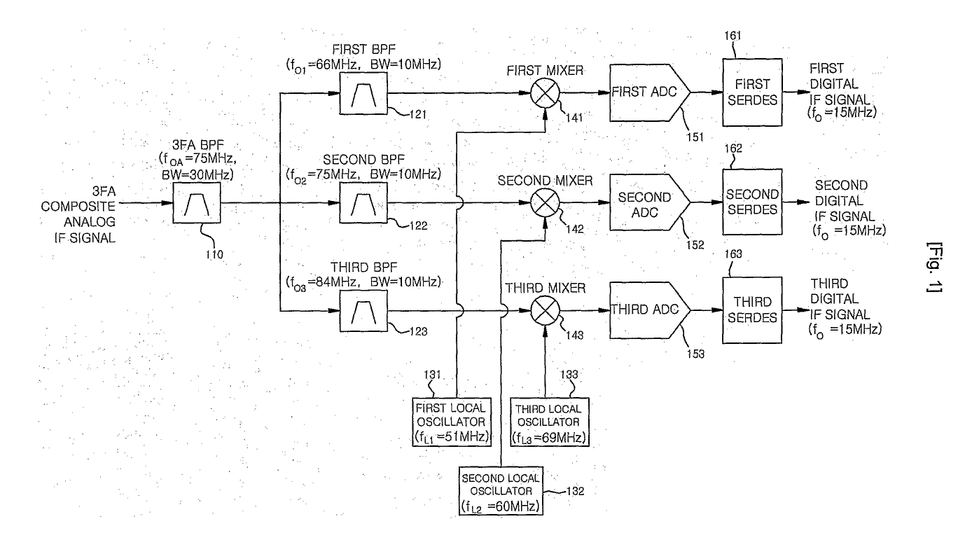

FIG. 2 is a block diagram illustrating the structure of an apparatus for digital frequency down-conversion according to an embodiment of the present invention;

FIGS. 3a to 3c are views illustrating a process for performing the digital frequency down-conversion by each frequency;

FIG. 4 is a block diagram illustrating the structure of an apparatus for digital frequency down-conversion according to another embodiment of the present invention;

FIG. 5 is a view illustrating examples in which the apparatus for digital frequency down-conversion illustrated in FIG. 4 is embodied by using a MATrix LABoratory (MATLAB) system generator;

FIG. 6 is a flowchart illustrating a method for digital frequency down-conversion according to an exemplary embodiment of the present invention; and

FIGS. 7a and 7b are detailed flowcharts illustrating the method for digital frequency down-conversion illustrated in FIG. 6.

### MODE FOR THE INVENTION

Hereinafter, an exemplary embodiment of the present invention will be described in detail with reference to the accompanying drawings. Well known functions and constructions are not described in detail since they would obscure the invention in unnecessary detail.

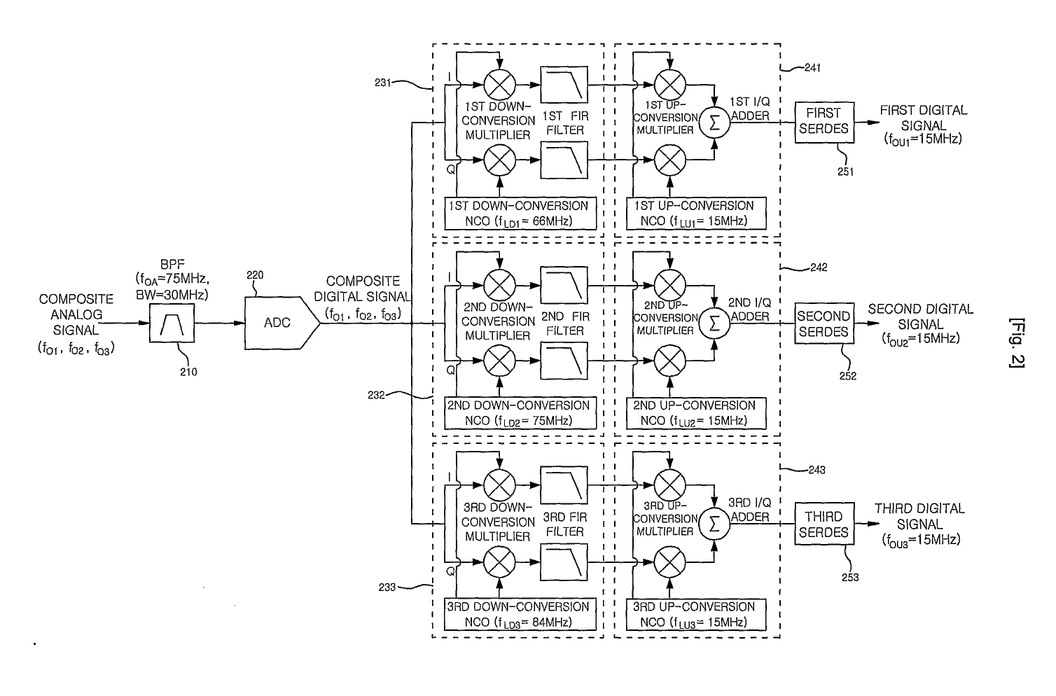

FIG. 2 is a block diagram illustrating the structure of an apparatus for digital frequency down-conversion according to an embodiment of the present invention. The present invention can be applied to an apparatus for digital frequency down-conversion which receives a signal to which at least two frequencies are allocated, down-converts frequencies of the received signal according to each FA, and outputs the down-converted signals. The present embodiment is applied the principles of the present invention to an apparatus for digital frequency down-conversion which receives a signal to which three frequencies are allocated, and outputs three (i.e., FA1, FA2, and FA3) digital signals. Also, to facilitate the following description, an input signal is set to a 3FA composite analog signal having the center frequencies of about 66[MHz] (FA1), 75 [MHz] (FA2), and 84 [MHz] (FA3). Herein, the 3FA composite analog signal is separated by frequencies, and is provided as first, second, and third digital signals, all having the reference center frequency of about 15 [MHz]. However, it will be apparent the center frequency of a signal generated in an embodiment of the present invention can be allowed in a certain error range according to ambient conditions or circumstances.

As illustrated in FIG. 2, the apparatus for digital frequency down-conversion according to the present invention includes a BPF 210, an ADC 220, down-converters 231, 232 and 233, up-converters 241, 242 and 243, and SerDeses 251, 252 and 253, etc.

For starters, the BPF 210 filters the 3FA composite analog signal of f_{O1}=66 [MHz], f_{O2}=75 [MHz], and f_{O3}=84 [MHz] with f_{OA}=75 [MHz] and BW=30 [MHz], and provides a filtered 3FA composite analog signal to the ADC 220.

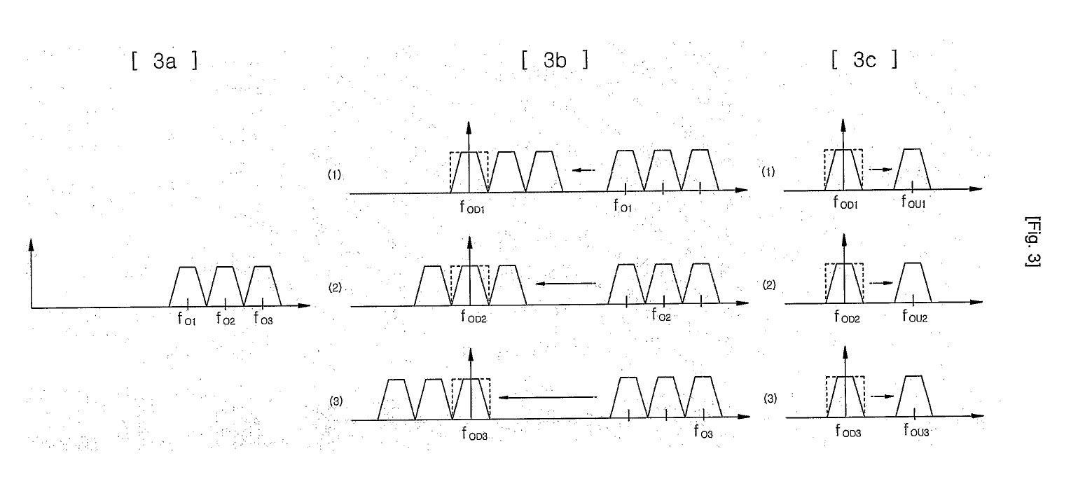

Then, the ADC 220 converts the filtered 3FA composite analog signal into an n-bit (n is a natural number) 3FA (f_{O1}=66 [MHz], f_{O2}=75 [MHz], and f_{O3}=84 [MHz]) composite digital signal having a data rate of about 120 [Mbps] by using a sampling clock of, e.g., 120 [MHz], and transmits a converted 3FA composite digital signal to the down-converters (refer to FIG. 3a).

The down-converters 231, 232, and 233 down-convert the 3FA composite digital signal provided from the ADC according to each FA (refer to FIG. 3b). Namely, the first down-converter 231 receives the 3FA composite digital signal of the center frequencies f_{O1}, f_{O2}, and f_{O3}, and converts the first digital signal whose center frequency corresponds to f_{O1} into a first baseband digital signal. The second down-converter 232 receives the 3FA composite digital signal of the center frequencies f_{O1}, f_{O2}, and f_{O3}, and converts the second digital signal whose center frequency corresponds to f_{O2} into a second baseband digital signal. The third down-converter 233 receives the 3FA composite digital signal of the center frequencies f_{O1}, f_{O2}, and f_{O3}, and converts the third digital signal whose center frequency corresponds to f_{O3} into a third baseband digital signal.

For this, each down-converter includes a down-conversion Numerically Controlled Oscillator (NCO), a down-conversion multiplier, and a Finite Impulse Response (FIR) filter.

Specifically, the first down-conversion NCO generates a local digital signal of a local frequency f_{LD1}=66 [MHz], and provides the local digital signal of the local frequency f_{LD1} to the first down-conversion multiplier. The first down-conversion multiplier multiplies the 3FA composite digital signal of the center frequencies f_{O1}, f_{O2}, and f_{O3} by the local digital signal of the local frequency f_{LD1}=66 [MHz], and generates a 3FA composite digital signal of the center frequencies 0 [Hz] (f_{O1}−f_{LD1}), 9 [MHz] (f_{O2}−f_{LD1}), and 18 [MHz] (f_{O3}−f_{LD1}). Then, the 3FA composite digital signal generated in this way passes through the first FIR filter with the center frequency of 0 [Hz] and BW=9 [MHz], which removes an FA2 component, an FA3 component, and harmonic components from the 3FA composite digital signal, and which generates a first baseband digital signal.

In the manner similar to this, the second down-conversion NCO generates a local digital signal of a local frequency f_{LD2}=75 [MHz], and provides the local digital signal of the local frequency f_{LD2} to the second down-conversion multiplier. The second down-conversion multiplier multiplies the 3FA composite digital signal of the center frequencies f_{O1}, f_{O2}, and f_{O3} by the local digital signal of the local frequency f_{LD2}=75 [MHz], and generates a 3FA composite digital signal of the center frequencies −9 [MHz] (f_{O1}−f_{LD2}), 0 [Hz] (f_{O2}−f_{LD2}), and 9 [MHz] (f_{O3}−f_{LD2}). Then, the 3FA composite digital signal generated in this way passes through the second FIR filter with the center frequency of 0 [Hz] and BW=9 [MHz], which removes an FAI component, an FA3 component, and harmonic components from the 3FA composite digital signal, and which generates a second baseband digital signal.

In addition, the third down-conversion NCO generates a local digital signal of a local frequency f_{LD3}=84 [MHz], and provides the local digital signal of the local frequency f_{LD3} to the third down-conversion multiplier. The third down-conversion multiplier multiplies the 3FA composite digital signal of the center frequencies f_{O1}, f_{O2}, and f_{O3} by the local digital signal of the local frequency f_{LD3}=84 [MHz], and generates a 3FA composite digital signal of the center frequencies −18 [MHz] (f_{O1}−f_{LD3}), −9 [MHz] (f_{O2}−f_{LD3}), and 0 [Hz] (f_{O3}−f_{LD3}). Then, the 3FA composite digital signal generated in this way passes through the third FIR filter with the center frequency of 0 [Hz] and BW=9 [MHz], which removes an FA1 component, an FA2 component, and harmonic components from the 3FA composite digital signal, and which generates a third baseband digital signal.

In the meantime, the up-converters 241, 242, and 243 up-convert the digital signals provided from the down-converters (refer to FIG. 3c). Namely, the first up-converter 241 receives the first digital signal of the center frequency f_{OD1}=f_{O1}−f_{LD1}=0 [Hz], converts the received first digital signal into a first digital signal of the center frequency f_{OU1}=15 [MHz] lower than f_{O1}=66 [MHz], and outputs the first digital signal of the center frequency f_{OU1}. The second up-converter 242 receives the second digital signal of the center frequency f_{OD2}=f_{O2}−f_{LD2}=0 [Hz], converts the received second digital signal into a second digital signal of the center frequency f_{OU2}=15 MHz] lower than f_{O2}=75 MHz], and outputs the second digital signal of the center frequency f_{OU2}. The third up-converter 243 receives the third digital signal of the center frequency f_{OD3}=f_{O3}−f_{LD3}=0 [Hz], converts the received third digital signal into a third digital signal of the center frequency f_{OU3}=15 MHz] lower than f_{O3}=84 MHz], and outputs the third digital signal of the center frequency f_{OU3}.

For this, each up-converter includes an up-conversion NCO and an up-conversion multiplier. In detail, the first up-conversion NCO generates a local digital signal of a local frequency f_{LU1}=15 [MHz], and provides the local digital signal of the local frequency f_{LU1} to the first up-conversion multiplier. The first up-conversion multiplier multiplies the first digital signal of the center frequency f_{OD1}=0 [Hz] by the local digital signal of the local frequency f_{LU1}=15 [MHz], and generates a first digital signal of the center frequency f_{OU1}=f_{OD1}+f_{LU1}=15 [MHz]. Likewise, the second up-conversion NCO generates a local digital signal of a local frequency f_{LU2}=15 [MHz], and provides the local digital signal of the local frequency f_{LU2} to the second up-conversion multiplier. The second up-conversion multiplier multiplies the second digital signal of the center frequency f_{OD2}=0 [Hz] by the local digital signal of the local frequency f_{LU2}=15 [MHz], and generates a second digital signal of the center frequency f_{OU2}=f_{OD2}+f_{LU2}=15 [MHz]. The third up-conversion NCO generates a local digital signal of a local frequency f_{LU3}=15 [MHz], and provides the local digital signal of the local frequency f_{LU3} to the third up-conversion multiplier. The third up-conversion multiplier multiplies the third digital signal of the center frequency f_{OD3}=0 [Hz] by the local digital signal of the local frequency f_{LU3}=15 [MHz], and generates a third digital signal of the center frequency f_{OU3}=f_{OD3}+f_{LU3}=15 [MHz]. For reference, in the present embodiment, f_{OU}=f_{OU1}=f_{OU2}=f_{OU3}=15 [MHz] is applied to the reference center frequency that meets standard requirements.

Meanwhile, in a case where a digital signal corresponds to a complex signal, an In-phase (I) component and a Quadature-phase (Q) component are processed following the separation of the I and Q components from the complex signal, and following the performance of a required operation, the digital sum is performed by an I/Q adder. In FIG. 2, a structure in which the down-converters and the up-converters process I and Q components following the separation thereof is illustrated by different paths, and in order to avoid the use of complicated terms, a multiplier and an FIR filter which respectively process the I and Q components are not denoted by using distinguished terms.

Lastly, the SerDeses 251, 252, and 253 convert digital IF signals provided in parallel from the up-converters into serial IF signals, and transmit converted digital IF signals to channel cards. Namely, the first, second, and third SerDeses convert the first, second, and third digital signals respectively having the center frequencies f_{OU1}, f_{OU2}, and f_{OU3} respectively provided from the first, second, and third up-converters in parallel into serial signals, and transmit converted first, second, and third digital signals to the channel cards, respectively.

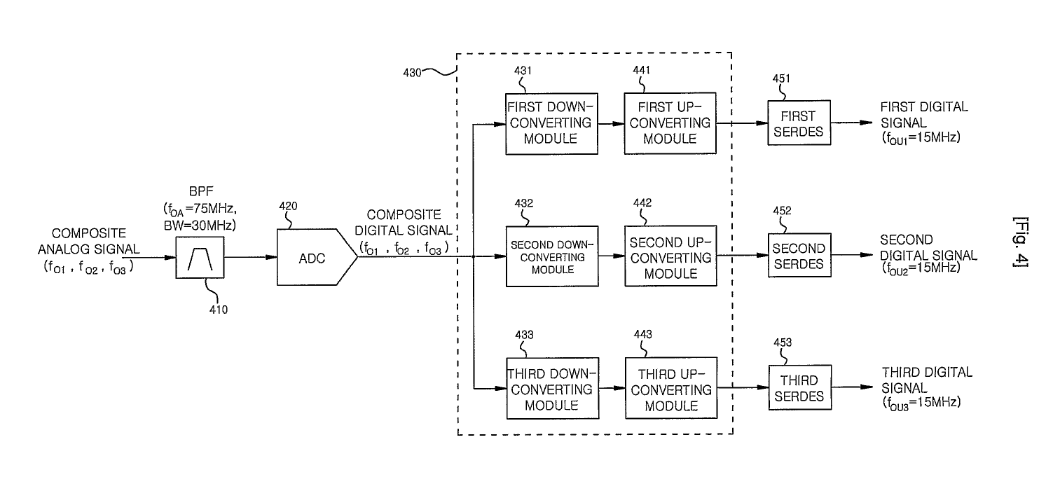

FIG. 4 is a block diagram illustrating the structure of an apparatus for digital frequency down-conversion according to another embodiment of the present invention. It is the apparatus for digital frequency down-conversion according to another embodiment of the present invention that the down-converters and the up-converters in the apparatus according to FIG. 2 are embodied in a single FPGA.

As illustrated in FIG. 4, the apparatus for digital frequency down-conversion according to the present invention includes a BPF 410, an ADC 420, an FPGA 430, SerDeses 451, 452 and 453, etc.

Herein, the BPF, the ADC, and the SerDeses are formed in the same manner as seen in the aforementioned description, and hereinafter, only the FPGA 430 will be described in detail.

The FPGA corresponds to an Integrated Circuit (IC) having a feature such that the FPGA can be used to be programmed as a user's requirement arises, and in the present invention, is configured to include down-converting modules, and up-converting modules.

The down-converting modules 431, 432, and 433 correspond to the down-converters illustrated in FIG. 2, and separate 3FA composite IF digital signal provided from the

ADC, according to each frequency, down-convert the IF digital signals into digital signals having the frequencies in the baseband. Namely, the first, second, and third down-converting modules 431, 432, 433 all receive the 3FA composite digital signal having the center frequencies f_{O1}, f_{O2}, and f_{O3}, and respectively down-convert the received 3FA composite digital signal having the center frequencies f_{O1}, f_{O2}, and f_{O3} into first, second, and third digital signals respectively having the center frequencies f_{OD1}, f_{OD2}, and f_{OD3}. For this, each down-converting module is configured to include a NCO function for down-conversion, a multiplying function for down-conversion, and a function of FIR filter.

The up-converting modules 441, 442, and 443 correspond to the up-converters illustrated in FIG. 2, and up-convert frequencies of digital signals provided from the down-converting modules. Namely, the first, second, and third up-converting modules 441, 442, and 443 receive the first, second, and third digital signals having the center frequencies f_{OD1}, f_{OD2}, and f_{OD3}, and up-convert the received first, second, and third digital signals having the center frequencies f_{OD1}, f_{OD2}, and f_{OD3} into first, second, and third digital signals having the center frequencies f_{OU1}, f_{OU2}, and f_{OU3}, respectively. For this, each up-converting module is configured to include an NCO function for up-conversion, and a multiplying function for up-conversion.

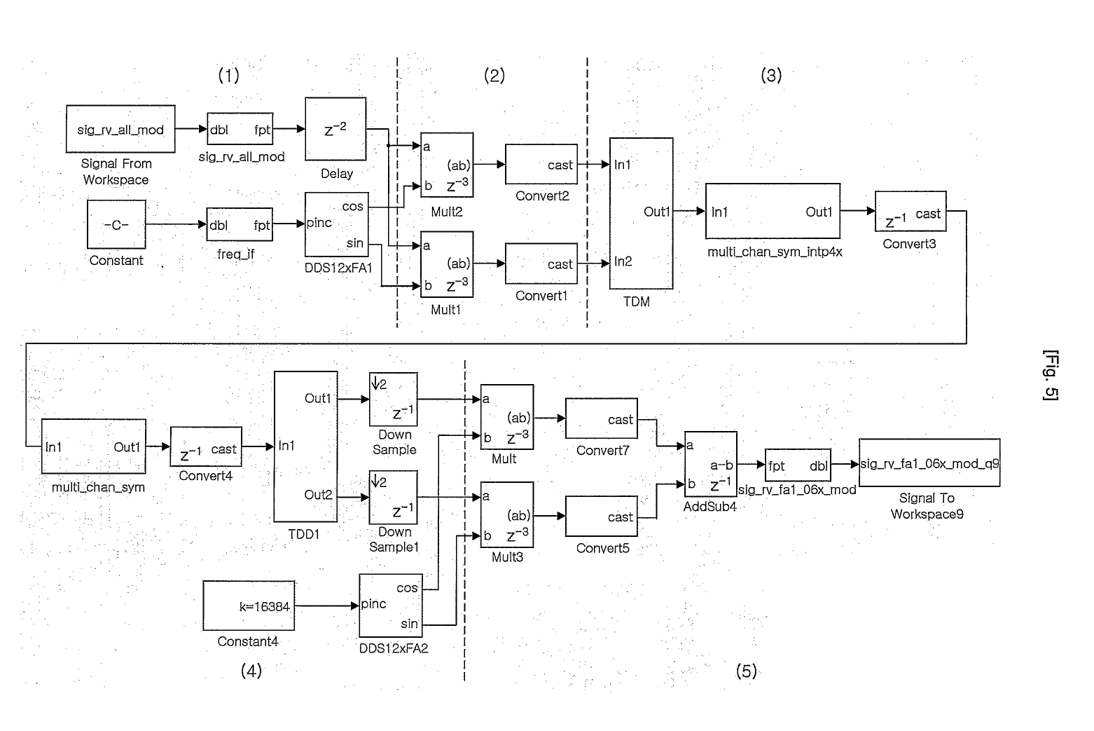

An FPGA according to the present invention can be implemented by using Very high speed integrated circuit Hardware Description Language (VHDL), etc., and can be desirably accomplished by using a system generator of the MATLAB. FIG. 5 is a view illustrating a down-converting module and an up-converting module related to a 1FA digital signal, embodied by using the system generator of the MATLAB, respectively. Hereinafter, a process of a signal will be described to take, as an example, a case where a first digital signal including one frequency has f_{O1}=66 [MHz], f_{LD1}=66 [MHz], f_{LU1}=15 [MHz], and f_{OU1}=15 [MHz].

For starters, ‘Part (1)’ illustrated in FIG. 5 corresponds to a process for converting the format of a 3FA composite digital signal having a data rate of 120 [Mbps] and the center frequencies of f_{O1}=66 [MHz] (FA1), f_{O2}=75 [MHz] (FA2), and f_{O3}=84 [MHz] (FA3) from double precision floating point to single precision floating point, and for, aside from this, generating a local signal of 66 [MHz] (related to FA1) for down-converting frequencies to the baseband. ‘Part (2)’ illustrated in FIG. 5 corresponds to a process for multiplying, by a local signal of 66 [MHz], the 3FA composite digital signal having a data rate of 120 [Mbps] and the center frequencies of 66 [MHz], 75 [MHz], and 84 [MHz] whose I and Q components are separated therefrom. ‘Part (3)’ illustrated in FIG. 5 corresponds to a process for time division duplexing, by using a Time Division Multiplexer (TDM), the signal whose I and Q components are separated, filtering a multiplexed signal in an FIR filter with the center frequency of 0 [Hz] and BW=9 [MHz], and generating a first baseband digital signal. A desired frequency is extracted by eliminating harmonic components through this filtering process. Accordingly, it is obtained to satisfy an output InterModulation and Distortion (IMD) performance. For reference, the first digital signal provided at this time has a data rate of 240 [Mbps] by the time division duplexing. ‘Part (4)’ illustrated in FIG. 5 corresponds to a process for separating an I component (120 [Mbps]) and a Q component (120 [Mbps]) from the first baseband digital signal by using Time Division Duplex (TDD), down-sampling the I and Q components twice to make 60 [Mbps], and aside from this, generating a local signal of 15 [MHz] for up-conversion. Finally, ‘Part (5)’ illustrated in FIG. 5 corresponds to a process for respectively multiplying the first baseband signal whose I component (60 [Mbps]) and Q component (60 [Mbps]) have been separated therefrom by the local signal of 15 [MHz], up-converting the first baseband signal a the signal of 15 [MHz], summing up the I and Q components, and converting the format of summed I and Q components from single precision floating point to double precision floating point.

For reference, in the above embodiments, the description thereof has been made with setting the reference center frequency and the data rate of a digital signal provided to the outside (e.g., channel cards) to 15 [MHz] and 60 [Mbps], respectively, and the reference center frequency and the data rate corresponds to values that can be varied according to interface specifications.

Hereinafter, a method for digital frequency down-conversion according to the present invention will be described. As a specific process or the principles of a detailed operation can be understood with reference to the aforementioned description of the apparatus for digital frequency down-conversion, a detailed description of overlapping contents will be avoided, and a brief description will be made on the basis of steps generated in time series in the following.

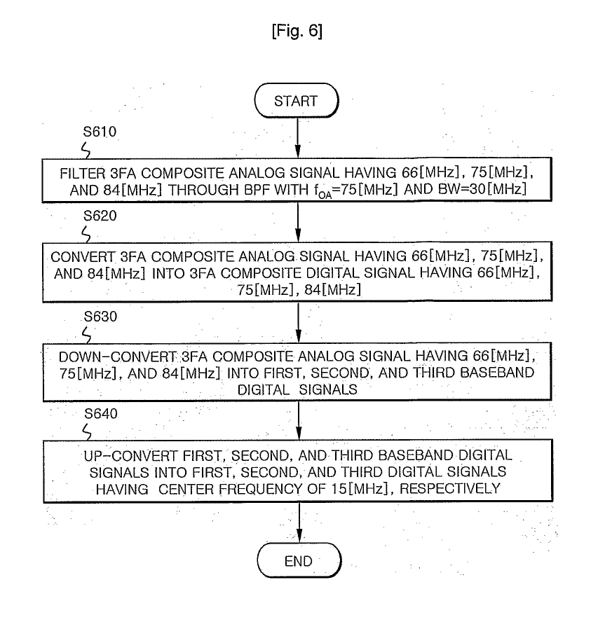

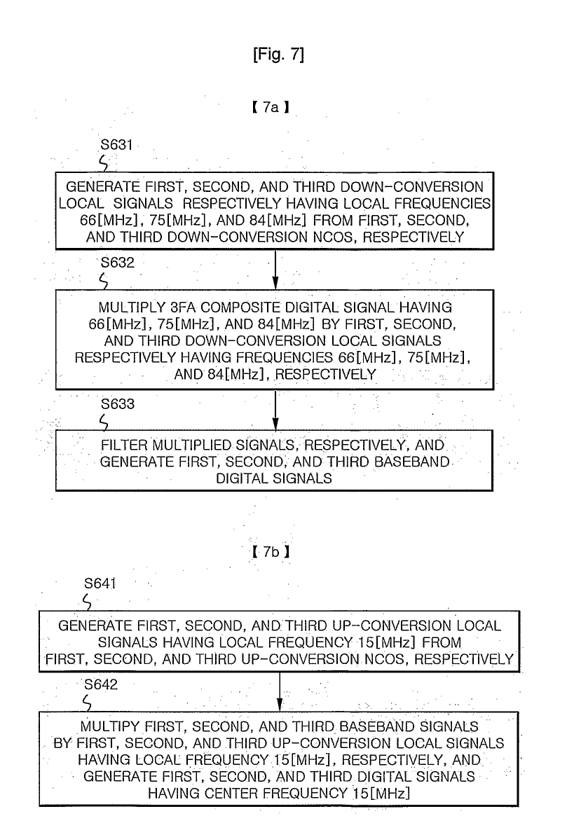

FIG. 6 is a flowchart illustrating a method for digital frequency down-conversion according to an exemplary embodiment of the present invention. FIGS. 7a and 7b are detailed flowcharts illustrating the method for digital frequency down-conversion illustrated in FIG. 6, which are applied to a method for digital frequency down-conversion related to a signal having three frequencies.

First, in step S610, the BPF filters a 3FA composite analog signal having the center frequencies of f_{O1}=66 [MHz] (FA1), f_{O2}=75 [MHz] (FA2), and f_{O3}=84 [MHz] (FA3) with f_{OA}=75 [MHz] and BW=30 [MHz].

In step S620, the ADC converts the 3FA composite analog signal of 66 [MHz], 75 [MHz] and 84 [MHz] into a 3FA composite digital signal of 66 [MHz], 75 [MHz] and 84 [MHz].

In step S630, the first, second, and third down-converters down-convert the 3FA composite digital signal of 66 [MHz], 75 [MHz] and 84 [MHz] into first, second, and third baseband digital signals, respectively. Particularly, the first, second, and third down-conversion NCOs respectively generate first, second, and third local signals for down-conversion respectively having local frequencies f_{LD1}=66 [MHz], f_{LD2}=75 [MHz], and f_{LD3}=84 [MHz] (S631). Then, the first, second, and third down-conversion multipliers respectively multiply the 3FA composite digital signal of 66 [MHz], 75 [MHz], and 84 [MHz] by the first, second, and third local signals for down-conversion respectively having the local frequencies f_{LD1}=66 [MHz], f_{LD2}=75 [MHz], and f_{LD3}=84 [MHz] (S632). Multiplied signals are respectively filtered by the first, second, and third FIR filters, all having the center frequency of 0 [Hz] and BW=9 [MHZ], and then, first, second, and third baseband digital signals, all having the center frequency f_{OD1}=f_{OD2}=f_{OD3}=0 [Hz], are produced.

Finally, in step S640, the first, second, and third up-converters respectively up-convert the first, second, and third baseband digital signals into first, second, and third digital signals, all having the center frequency f_{OU1}=f_{OU2}=f_{OU3}=15 [MHz] (the reference center frequency: f_{OU}). Particularly, the first, second, and third up-conversion NCOs respectively generate first, second, and third local signals for up-conversion, all having a local frequency f_{LU1}=f_{LU2}=f_{LU3}=15 [MHz] (f_{LU}) (S641). Then, the first, second, and third up-conversion multipliers respectively multiply the first, second, and third baseband digital signals, all having the center frequency f_{OD1}=f_{OD2}=f_{OD3}=0 [Hz], by the first, second, and third local signals for up-conversion, all having the local frequency f_{LU1}=f_{LU2}=f_{LU3}=15 [MHz] (f_{LU}), and respectively generate first, second, and third digital signals, all having the center frequency f_{OU1}=f_{OU2}=f_{OU3}=15 [MHz] (f_{OU}) (S642).

While this invention has been described in connection with what is presently considered to be the most practical and preferred embodiment, it is to be understood that the invention is not limited to the disclosed embodiment and the drawings, but, on the contrary, it is intended to cover various modifications and variations within the spirit and scope of the appended claims.

1. An apparatus for digital frequency down-conversion, the apparatus comprising:
a first down-converter for receiving a composite digital signal having the center frequencies f_{O1} and f_{O2}, which includes a first digital signal of the center frequency f_{O1} and a second digital signal of the center frequency f_{O2}, and converting the first digital signal of the center frequency f_{O1} into a first baseband digital signal;
a second down-converter for receiving the composite digital signal having the center frequencies f_{O1} and f_{O2}, and converting the second digital signal of the center frequency f_{O2} into a second baseband digital signal;
a first up-converter for receiving the first baseband digital signal from the first down-converter, and converting the received first baseband digital signal into a first digital signal of the reference center frequency f_{OU} lower than the mean of the center frequencies f_{O1} and f_{O2}; and
a second up-converter for receiving the second baseband digital signal from the second down-converter, and converting the received second baseband digital signal into a second digital signal of the reference center frequency f_{OU} lower than the mean of the center frequencies f_{O1} and f_{O2}.

2. The apparatus as claimed in claim 1, which further comprises an Analog-to-digital converter (ADC) for converting the composite analog signal having the center frequencies f_{O1} and f_{O2} into the composite digital signal having the center frequencies f_{O1} and f_{O2}, and providing the composite digital signal to the first down-converter and the second down-converter respectively.

3. The apparatus as claimed in claim 2, which further comprises a Band-Pass Filter (BPF) for filtering the composite analog signal of the center frequencies f_{O1} and f_{O2}, and providing a filtered composite analog signal to the ADC.

4. The apparatus as claimed in claim 1, further comprising:
a first Serializer/Deserializer (SerDes) for converting the first parallel digital signal of the reference center frequency f_{OU} provided from the first up-converter into a first serial digital signal of the reference center frequency f_{OU}; and
a second SerDes for converting the second parallel digital signal of the reference center frequency f_{OU} provided from the second up-converter into a second serial digital signal of the reference center frequency f_{OU}.

5. The apparatus as claimed in claim 1, wherein the first down-converter comprises:
a first down-conversion Numerically Controlled Oscillator (NCO) for generating
a first down-conversion local signal of a local frequency f_{LD1};
a first down-conversion multiplier for multiplying the composite digital signal having the center frequencies f_{O1} and f_{O2} by the first down-conversion local signal of the local frequency f_{LD1}; and
a first Finite Impulse Response (FIR) filter for filtering a first multiplied digital signal provided from the first down-conversion multiplier,
and wherein the second down-converter comprises:
a second down-conversion NCO for generating a second down-conversion local signal of a local frequency f_{LD2};
a second down-conversion multiplier for multiplying the composite digital signal having the center frequencies f_{O1} and f_{O2} by the second down-conversion local signal of the local frequency f_{LD2}; and
a second Finite Impulse Response (FIR) filter for filtering a second multiplied digital signal provided from the second down-conversion multiplier.

6. The apparatus as claimed in claim 1, wherein the first up-converter comprises:
a first up-conversion NCO for generating a first up-conversion local signal of a local frequency f_{LU}; and
a first up-conversion multiplier for multiplying the first baseband digital signal by the first up-conversion local signal of the local frequency f_{LU},
and wherein a second up-converter comprises:
a second up-conversion NCO for generating a second up-conversion local signal of a local frequency f_{LU}; and
a second up-conversion multiplier for multiplying the second baseband digital signal by the second up-conversion local signal of the local frequency f_{LU}.

7. The apparatus as claimed in claim 1, wherein the first down-converter and the first up-converter perform conversions by separating an In-phase (I) component and a Quadrature-phase (Q) component from the first digital signal, and the second down-converter and the second up-converter perform conversions by separating an I component and a Q component from the second digital signal.

8. The apparatus as claimed in claim 1, wherein the composite digital signal further comprises a third digital signal having the center frequency f_{O3} to have the center frequencies f_{O1}, f_{O2}, and f_{O3},
further comprising:
a third down-converter for receiving the composite digital signal having the center frequencies f_{O1}, f_{O2}, and f_{O3}, and converting the third digital signal of the center frequency f_{O3} into a third baseband digital signal; and
a third up-converter for receiving the third baseband digital signal provided from the third down-converter, and converting the received third baseband digital signal into a third digital signal of the center frequency f_{OU}.

9. The apparatus as claimed in claim 8, wherein the center frequencies f_{O1}, f_{O2}, and f_{O3} correspond to 66 MHz, 75 MHz, and 84 MHz, respectively.

10. The apparatus as claimed in claim 9, which further comprises an ADC for converting a composite analog signal having the center frequencies of about f_{O1}=66 [MHz], f_{O2}=75 [MHz], and f_{O3}=84 [MHz] into a composite digital signal having the center frequencies of about f_{O1}=66 [MHz], f_{O2}=75 [MHz], and f_{O3}=84 [MHz], and providing the composite digital signal to the first, second, and third down-converters respectively.

11. An apparatus for digital frequency down-conversion, the apparatus comprising: an Analog-to-Digital Converter (ADC) for converting a composite analog signal having at least two center frequencies into a composite digital signal having at least two center frequencies;
a Field Programmable Gate Array (FPGA) for receiving the composite digital signal from the ADC, respectively down-converting at least two digital signals having each center frequency included in the composite digital signal into baseband digital signals, and respectively up-converting the baseband digital signals into digital signals having the reference center frequency; and
a Serializer/Deserializer (SerDes) for converting the parallel digital signals of the reference center frequency provided from the FPGA into the serial digital signals of the reference center frequency.

12. The apparatus as claimed in claim 11, wherein the FPGA comprises:
a down-converting module for respectively converting the at least two digital signals having each center frequency included in the composite digital signal into the baseband digital signals; and
an up-converting module for respectively converting the baseband digital signals into the digital signals having the reference center frequency.

13. The apparatus as claimed in claim 11, further comprising a Band-Pass Filter (BPF) for filtering the composite analog signal having the at least two center frequencies, and providing a filtered composite analog signal to the ADC.

14. The apparatus as claimed in claim 11, wherein the reference center frequency corresponds to about 15 MHz.

15. The apparatus as claimed in claim 11, wherein the FPGA perform conversions by separating In-phase (I) components and Quadrature-phase (Q) components from the digital signals.

16. The apparatus as claimed in claim 11, wherein the FPGA is configured by using a system generator of MATrix LABoratory (MATLAB).

17. A method for digital frequency down-conversion, the method comprising the steps of:
(a) separating first and second digital signals respectively having the center frequencies f_{O1} and f_{O2} from a composite digital signal having the center frequencies f_{O1} and f_{O2}, and down-converting the composite digital signal having the center frequencies f_{O1} and f_{O2} into first and second baseband digital signals; and
(b) up-converting the first and second baseband digital signals into first and second digital signals having the reference center frequency f_{OU} lower than the center frequencies f_{O1} and f_{O2}, respectively.

18. The method as claimed in claim 17, which further comprises a step of (c) converting the first and second digital signals having the reference center frequency f_{OU}, from parallel signals to serial signals, respectively.

19. The method as claimed in claim 17, which further comprises a step of converting a composite analog signal having the center frequencies f_{O1} and f_{O2} into the composite digital signal having the center frequencies f_{O1} and f_{O2}, wherein the step of converting the composite analog signal having the center frequencies f_{O1} and f_{O2} precedes step (a).

20. The method as claimed in claim 17, wherein step (a) comprises the steps of:
(a-1) generating a first down-conversion local signal of a local frequency f_{LD1} and a second down-conversion local signal of a local frequency f_{LD2};
(a-2) multiplying the composite digital signal having the center frequencies f_{O1} and f_{O2} by the first down-conversion local signal of the local frequency f_{LD1}, and multiplying the composite digital signal having the center frequencies f_{O1} and f_{O2} by the second down-conversion local signal of the local frequency f_{LD2}; and
(a-3) generating baseband digital signals respectively by filtering the multiplied signals.

21. The method as claimed in claim 17, wherein step (b) comprises the steps of:
(b-1) generating first and second up-conversion local signals of a local frequency f_{LU}; and
(b-2) generating a first digital signal of the reference center frequency f_{OU} lower than the center frequency f_{O1} by multiplying the first baseband digital signal by the first up-conversion local signal of the local frequency f_{LU}, and generating a second digital signal of the reference center frequency f_{OU} lower than the center frequency f_{O2} by multiplying the second baseband digital signal by the second up-conversion local signal of the local frequency f_{LU}.
